(19) United States
(12) Patent Application Publication
(10) Pub. No.: US 2015/0351228 A1
(43) Pub. Date: Dec. 3, 2015

(54) PACKAGE BOARD AND METHOD FOR MANUFACTURING THE SAME

(71) Applicant: SAMSUNG ELECTRO-MECHANICS CO., LTD., Suwon-Si (KR)

(72) Inventors: Jin Seon PARK, Suwon-Si (KR); Myung Sam Kang, Suwon-Si (KR); Seung Eun Lee, Suwon-Si (KR); Seung Yeop Kook, Suwon-Si (KR); Ki Jung Sung, Suwon-Si (KR); Ju Hee Park, Suwon-Si (KR); Je Gwang Yoo, Suwon-Si (KR)

(73) Assignee: SAMSUNG ELECTRO-MECHANICS CO., LTD., Suwon-Si (KR)

(21) Appl. No.: 14/463,468

(22) Filed: Aug. 19, 2014

(30) Foreign Application Priority Data
May 30, 2014 (KR) 10-2014-0066389

(51) Int. Cl. H05K 1/02; H05K 1/18; H05K 3/40; H05K 1/11; H01L 23/522; H05K 3/30

(52) U.S. Cl. CPC H05K 1/0231; H01L 23/522; H05K 3/30; H05K 3/4038; H05K 1/115; H05K 1/185; H05K 1/0298

(57) ABSTRACT

There are provided a package board and a method for manufacturing the same. According to an exemplary embodiment of the present disclosure, a package board includes: a first insulating layer; a second insulating layer formed beneath the first insulating layer; a capacitor embedded in the first insulating layer and including a first electrode, a second electrode, and a dielectric layer formed between the first electrode and the second electrode; circuit layers formed on the first insulating layer and the second insulating layer; and a via formed between the capacitor and the circuit layers or between the circuit layers formed on the first insulating layer and the second insulating layer to electrically connect thererbetween, wherein an upper surface of the first electrode is formed to be exposed from the first insulating layer.

### CROSS-REFERENCE TO RELATED APPLICATION

This application claims the foreign priority benefit of Korean Patent Application No. 10-2014-0066389, filed on May 30, 2014, entitled “Package Board And Method For Manufacturing The Same” which is hereby incorporated by reference in its entirety into this application.

### BACKGROUND

1. Technical Field

Embodiments of the present invention relate to a package board and a method for manufacturing the same.

2. Description of Related Art

With the rapid development of a semiconductor technology, a semiconductor device is remarkably growing. Further, the development for a semiconductor package such as a system in package (SIP), a chip sized package (CSP), and a flip chip package (FCP) configured as a package by mounting electronic devices such as the semiconductor device on a printed circuit board in advance has been actively conducted. Further, to improve miniaturization and performance of a high-performance smart phone, there is a package on package (POP) in which a control device and a memory device are implemented as one package form. The package on package may be implemented by individually packaging the control device and the memory device and stacking and connecting them (See U.S. Pat. No. 5,986,209).

### SUMMARY

An aspect of the present disclosure may provide a package board and a method for manufacturing a package board capable of reducing occurrence of noise due to an increase in an operating speed of a semiconductor device.

Another aspect of the present disclosure may provide a package board and a method for manufacturing a package board capable of improving warpage by improving rigidity of the package board.

Still another aspect of the present disclosure may provide a package board and a method for manufacturing a package board capable of improving reliability of signal transmission by reducing reactance.

According to an aspect of the present disclosure, a package board may include: a first insulating layer; a second insulating layer formed beneath the first insulating layer; a capacitor embedded in the first insulating layer and including a first electrode, a second electrode, and a dielectric layer formed between the first electrode and the second electrode; circuit layers formed on the first insulating layer and the second insulating layer; and a via formed between the capacitor and the circuit layers or between the circuit layers formed on the first insulating layer and the second insulating layer to electrically connect thererbetween, wherein an upper surface of the first electrode is formed to be exposed from the first insulating layer.

According to another aspect of the present disclosure, a package board may include: a first insulating layer; a second insulating layer formed beneath the first insulating layer; a capacitor embedded in the second insulating layer and including a first electrode, a second electrode, and a dielectric layer formed between the first electrode and the second electrode; circuit layers formed on the first insulating layer and the second insulating layer; and a via formed between the capacitor and the circuit layers or between the circuit layers formed on the first insulating layer and the second insulating layer to electrically connect thererbetween, wherein an upper surface of the first electrode is formed to be exposed from the second insulating layer.

According to another aspect of the present disclosure, a method for manufacturing a package board may include: forming a first circuit layer and a first electrode on a carrier board; forming a dielectric layer on the first electrode; forming a second electrode on the dielectric layer to form a capacitor including the first electrode, the dielectric layer, and a second electrode; forming a first insulating layer on the carrier board to embed the first circuit layer and the capacitor; forming a first via, a second via, and a second circuit layer on the first insulating layer; forming a second insulating layer on the first insulating layer to embed the second circuit layer; forming a third via and a third circuit layer on the second insulating layer; and removing the carrier board.

According to another aspect of the present disclosure, a method for manufacturing a package board may include: forming a first circuit layer on a carrier board; forming a first insulating layer on the carrier board to embed the first circuit layer; forming a second circuit layer, a first via, a second via, and a first electrode on the first insulating layer; forming a dielectric layer on the first electrode; forming a second electrode on the dielectric layer to form a capacitor including the first electrode, the dielectric layer, and a second electrode; forming a second insulating layer on the first insulating layer to embed the second circuit layer and the capacitor; forming a third via, a fourth via, and a third circuit layer on the second insulating layer; and removing the carrier board.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified diagram illustrating a package board according to an exemplary embodiment of the present disclosure;

FIGS. 2 through 23 are exemplified diagrams illustrating a method for manufacturing a package board according to the exemplary embodiment of the present disclosure;

FIG. 24 is an exemplified diagram illustrating a package board according to another exemplary embodiment of the present disclosure; and

FIGS. 25 through 31 are exemplified diagrams illustrating a method for manufacturing a package board according to another exemplary embodiment of the present disclosure.

### DETAILED DESCRIPTION

Features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### First Exemplary Embodiment

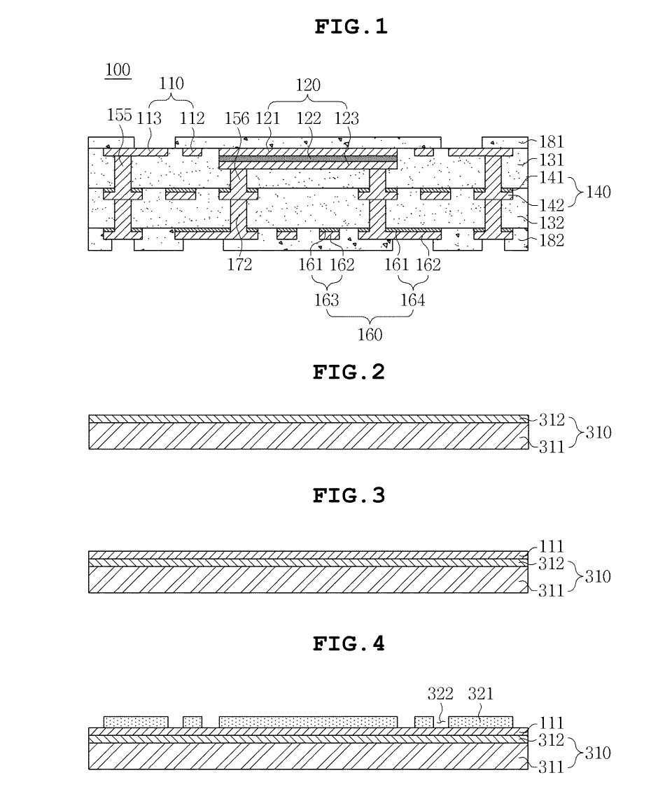

FIG. 1 is an exemplified diagram illustrating a package board according to an exemplary embodiment of the present disclosure.

Referring to FIG. 1, a package board 100 may include a first insulating layer 131, a second insulating layer 132, a first circuit layer 110 to a third circuit layer 160, a capacitor 120, a first via 155 to a third via 172, a first solder resist layer 181, and a second solder resist layer 182.

According to the first exemplary embodiment of the present disclosure, the first insulating layer 131 and the second insulating layer 132 may be generally made of a composite polymer resin used as an interlayer insulating material. For example, the first insulating layer 131 and the second insulating layer 132 may be made of an epoxy based resin, such as a prepreg, an ajinomoto build up film (ABF), FR-4, and bismaleimide triazine (BT). However, according to the first exemplary embodiment of the present disclosure, the material forming the first insulating layer 131 and the second insulating layer 132 is not limited thereto. The first insulating layer 131 and the second insulating layer 132 may be selected from insulating materials known in a circuit board field.

According to the first exemplary embodiment of the present disclosure, the second insulating layer 132 is formed beneath the first insulating layer 131.

According to the first exemplary embodiment of the present disclosure, the first circuit layer 110 is formed to be embedded in an upper portion of the first insulating layer 131. The so formed first circuit layer 110 includes a first circuit pattern 112 and a bonding pad 113. The bonding pad 113 may be electrically connected to a semiconductor device (not illustrated) when the semiconductor device (not illustrated) is mounted on the package board 100. For example, the bonding pad 113 may be connected to the semiconductor device (not illustrated) by a wire bonding scheme.

According to the first exemplary embodiment of the present disclosure, a second circuit layer 140 is formed to be embedded in an upper portion of the second insulating layer 132.

According to the first exemplary embodiment of the present disclosure, a third circuit layer 160 is formed beneath the second insulating layer 132. In this configuration, the third circuit layer is formed to protrude from the second insulating layer 132. The so formed third circuit layer 160 includes a third circuit pattern 163 and an external connection pad 164. The external connection pad 164 is electrically connected to external components. For example, the external components may be a semiconductor package, a package board, and the like.

The first circuit layer 110 to the third circuit layer 160 are made of a conductive material. For example, the first circuit layer 110 to the third circuit layer 160 are made of copper (Cu). However, the material forming the first circuit layer 110 to the third circuit 160 is not limited to copper. That is, any material which may be used as a conductive material for a circuit in a circuit board field may be applied to the first circuit layer 110 to the third circuit layer 160 without being limited.

Further, according to the first exemplary embodiment of the present disclosure, one of the first circuit layer 110 to the third circuit layer 160 may be a power layer and the other thereof may be a ground layer.

According to the first exemplary embodiment of the present disclosure, the capacitor 120 is formed to be embedded in the upper portion of the first insulating layer 131. For example, the capacitor 120 is a 3-layered thin film capacitor which includes a first electrode 121, a second electrode 123, and a dielectric layer 122. The dielectric layer 122 of the capacitor 120 is formed between the first electrode 121 and the second electrode 123. According to the first exemplary embodiment of the present disclosure, a horizontal section size of the capacitor 120 is formed to be equal or similar to that of the semiconductor device (not illustrated). As illustrated in FIG. 1, an upper surface of the first electrode 121 of the capacitor 120 is formed to be exposed from the first insulating layer 131. That is, the first electrode 121 of the capacitor 120 contacts the first solder resist layer 181.

The package board 100 according to the first exemplary embodiment of the present disclosure has the capacitor 120 embedded therein to be able to reduce occurrence of noise due to an increase in an operating speed of the semiconductor device (not illustrated) which is mounted later. Here, the semiconductor device (not illustrated) may be a memory device. Further, according to the first exemplary embodiment of the present disclosure, the capacitor 120 has a thin thickness and thus an increase in a thickness of the package board 100 is not large. That is, even when the package board 100 according to the first exemplary embodiment of the present disclosure has the capacitor 120 disposed therein, the thickness of the package board 100 is maintained thinly. Further, according to the first exemplary embodiment of the present disclosure, the horizontal section size of the capacitor 120 is formed to be equal or similar to that of the semiconductor device (not illustrated) and thus rigidity of the package board 100 is improved. Therefore, a warpage of the package board 100 is reduced. Further, according to the first exemplary embodiment of the present disclosure, the capacitor 120 is formed on the package board 100 and thus is disposed to be close to the semiconductor device (not illustrated). Therefore, the capacitor 120 is connected to the semiconductor device (not illustrated) at the shortest distance to improve signal transmission characteristics.

Although not illustrated in FIG. 1, the first electrode 121 of the capacitor 120 is formed to be partially bonded to the first circuit layer 110. In this case, when the first circuit layer 110 is the power layer, the first electrode 121 of the capacitor 120 may serve as the power layer.

According to the first exemplary embodiment of the present disclosure, the first via 155 is formed to penetrate through the first insulating layer 131. The first via 155 may electrically connect the first circuit layer 110 to the second circuit layer 140.

According to the first exemplary embodiment of the present disclosure, a second via 156 is formed to penetrate through the first insulating layer 131. The second via 156 may electrically connect the second electrode 123 of the capacitor 120 to the second circuit layer 140.

According to the first exemplary embodiment of the present disclosure, a third via 172 is formed to penetrate through the second insulating layer 132. The third via 172 may electrically connect the second circuit layer 140 to the third circuit layer 160.

The first via 155 to the third via 172 are made of a conductive material. For example, the first via 155 to the third via 172 are made of copper. However, the material forming the first via 155 to the third via 172 is not limited to copper. That is, any material which may be used as a conductive material for a via in the circuit board field may be applied to the first via 155 to the third via 172 without being limited.

According to the first exemplary embodiment of the present disclosure, the first solder resist layer 181 is formed on the first insulating layer 131. The first solder resist layer 181 is formed to enclose the first circuit layer 110 except for an area connected to the outside. Further, the first solder resist layer 181 is formed to enclose the first electrode 121 of the capacitor 120 which is exposed from the first insulating layer 131. That is, the first solder resist layer 181 encloses the first circuit pattern 112 and the capacitor 120 and is formed to expose the bonding pad 113.

According to the first exemplary embodiment of the present disclosure, the second solder resist layer 182 is formed beneath the second insulating layer 132. The second solder resist layer 182 is formed to enclose the third circuit layer 160 except for an area connected to the outside. That is, the second solder resist layer 182 encloses the third circuit pattern 163 and is formed to expose the external connection pad 164.

The first exemplary embodiment of the present disclosure describes that the solder resist layers are formed on the first insulating layer 131 and the second insulating layer 132, respectively, but is not limited thereto. That is, the solder resist layer may be formed or may not be formed on any one of the first insulating layer 131 and the second insulating layer according to the selection of those skilled in the art.

The first solder resist layer 181 and the second solder resist layer 182 protect the circuit patterns from soldering at the time of soldering which connects the semiconductor device or the external components to the package board 100. Further, the first solder resist layer 181 and the second solder resist layer 182 prevent the circuit patterns from being oxidized. The first solder resist layer 181 and the second solder resist layer 182 may be made of a heat resistant covering material.

FIGS. 2 through 23 are exemplified diagrams illustrating a method for manufacturing a package board according to the first exemplary embodiment of the present disclosure.

Referring to FIG. 2, a carrier board 310 may be prepared.

According to the first exemplary embodiment of the present disclosure, the carrier board 310 is formed by disposing a carrier metal layer 312 on a carrier core 311.

According to the first exemplary embodiment of the present disclosure, when the insulating layer, the circuit layer, and the like are formed on the package board, the carrier core 311 is to support the insulating layer, the circuit layer, and the like. The carrier core 311 may be made of an insulating material or a metal material or may be formed in a stacked structure. However, the carrier core 311 is not limited thereto, but any carrier which is used as a support board in the circuit board field and removed later may be applied to the carrier core 311.

According to the first exemplary embodiment of the present disclosure, the carrier metal layer 312 is made of copper. However, the material of the carrier metal layer 312 is not limited to copper, and therefore any material which may be used as the conductive material for the circuit in the circuit board field may be applied to the carrier metal layer 312 without being limited.

The first exemplary embodiment of the present disclosure describes a structure in which the carrier board 310 includes both of the carrier core 311 and the carrier metal layer 312, but is not limited thereto. For example, the carrier board 310 may be configured only of the carrier core 311. In this case, the carrier metal layer 312 is separately formed on the carrier core 311, thereby preparing the carrier board 310 according to the first exemplary embodiment of the present disclosure.

Referring to FIG. 3, the first metal layer 111 is formed.

According to the first exemplary embodiment of the present disclosure, the first metal layer 111 is formed on the carrier metal layer 312 of the carrier board 310. For example, the first metal layer 111 is formed by an electroplating method. In this case, the carrier metal layer 312 may be a seed layer for electroplating.

According to the first exemplary embodiment of the present disclosure, the first metal layer 111 is made of copper. However, the material of the first metal layer 111 is not limited to copper, and therefore any material which may be used as the conductive material for the circuit in the circuit board field may be applied to the first metal layer 111 without being limited.

Referring to FIG. 4, a first etching resist 321 is formed.

According to the first exemplary embodiment of the present disclosure, the first etching resist 321 is formed on the first metal layer 111.

The first etching resist 321 includes a first opening 322 through which an area to be removed from the first metal layer 111 is exposed. That is, the first etching resist 321 protects the area in which the first circuit layer (not illustrated) and the first electrode (not illustrated) of the capacitor (not illustrated) are formed and is formed to expose the area to be removed.

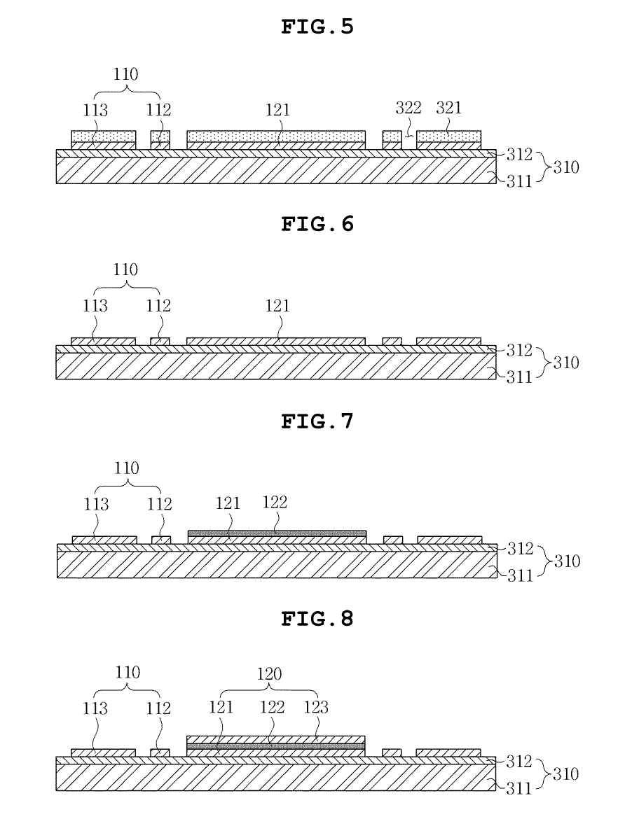

Referring to FIG. 5, the first circuit layer 110 and the first electrode 121 are formed.

According to the first exemplary embodiment of the present disclosure, an etching process is performed on the first metal layer 111 (FIG. 4). In this case, in the first metal layer 111 (FIG. 4), a portion at which the first etching resist 321 is formed is protected from the etching process and a portion exposed to the first opening 322 is removed. As such, the first circuit layer 110 and the first electrode 121 are formed by patterning the first metal layer 111 (FIG. 4).

According to the first exemplary embodiment of the present disclosure, the first circuit layer 110 includes the first circuit pattern 112 and the bonding pad 113. The bonding pad 113 may be electrically connected to the semiconductor device (not illustrated) when the semiconductor device (not illustrated) is mounted on the package board 100.

Although not illustrated in FIG. 5, the first electrode 121 is formed to be partially bonded to the first circuit layer 110. Therefore, when the first circuit layer 110 is the power layer, the first electrode 121 may also serve as the power layer.

Further, according to the first exemplary embodiment of the present disclosure, the horizontal section size of the first electrode 121 is equal or similar to that of the semiconductor device (not illustrated) which is mounted later.

Referring to FIG. 6, the first etching resist 321 (FIG. 5) is removed.

Referring to FIG. 7, the dielectric layer 122 is formed.

According to the first exemplary embodiment of the present disclosure, the dielectric layer 122 is formed on the first electrode 121. The dielectric layer 122 may be formed by a method for depositing a dielectric material or a method for printing a dielectric material.

Referring to FIG. 8, the second electrode 123 is formed.

According to the first exemplary embodiment of the present disclosure, the second electrode 123 is formed on the dielectric layer 122. The second electrode 123 is formed by at least one of an electroless plating method and an electroplating method. The second electrode 123 is made of copper. However, the material of the second electrode 123 is not limited to copper, and therefore any material which may be used as the conductive material for the circuit in the circuit board field may be applied to the second electrode 123 without being limited.

As such, the capacitor 120 is formed by forming the second electrode 123. According to the first exemplary embodiment of the present disclosure, the capacitor 120 is a 3-layered thin film capacitor which includes the first electrode 121, the second electrode 123, and the dielectric layer 122 formed between the first electrode 121 and the second electrode 123. In this case, the horizontal section size of the capacitor 120 is formed to be equal or similar to that of the semiconductor device (not illustrated) which is mounted. Further, according to the first exemplary embodiment of the present disclosure, the capacitor 120 is formed on the same layer as the bonding pad 113 and thus may be connected to the semiconductor device (not illustrated) at the shortest distance, thereby improving the signal transmission characteristics.

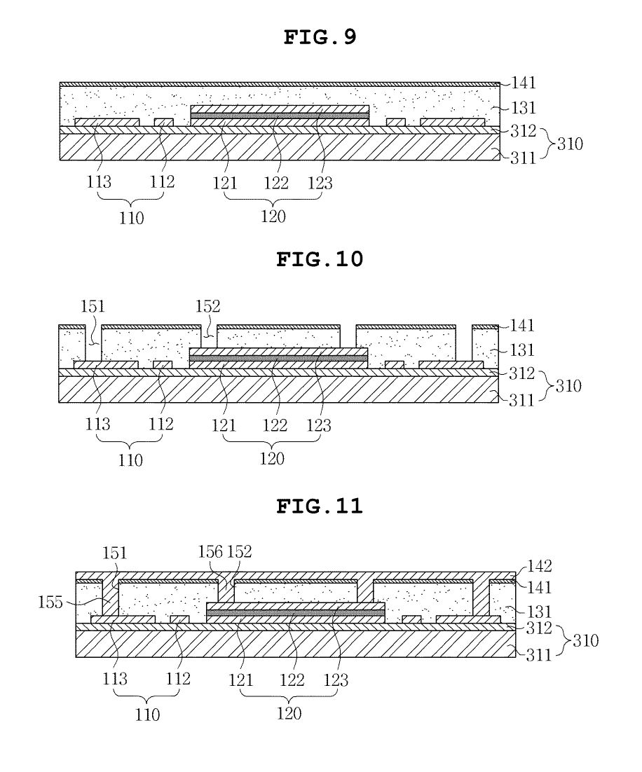

Referring to FIG. 9, the first insulating layer 131 and the second metal layer 141 are formed.

According to the first exemplary embodiment of the present disclosure, the first insulating layer 131 may be formed on the carrier metal layer 312 to embed the first circuit layer 110 and the first electrode 121. According to the first exemplary embodiment of the present disclosure, the first insulating layer 131 is formed by being stacked on the carrier metal layer 312 in a high temperature and pressure state. The first insulating layer 131 may be generally made of the composite polymer resin used as the interlayer insulating material. For example, the first insulating layer 131 may be made of the epoxy based resin, such as prepreg, ajinomoto build up film (ABF), FR-4, and bismaleimide triazine (BT). However, according to the first exemplary embodiment of the present disclosure, the material forming the first insulating layer 131 is not limited thereto. According to the first exemplary embodiment of the present disclosure, the first insulating layer 131 may be selected from insulating materials known in the circuit board field.

According to the first exemplary embodiment of the present disclosure, the second metal layer 141 is formed on the first insulating layer 131. For example, the second metal layer 141 may be made of copper. However, the material of the second metal layer 141 is not limited to copper, and therefore any material which may be used as the conductive material for the circuit in the circuit board field may be applied to the second metal layer 141 without being limited. The second metal layer 141 may be formed by the electroless plating method and the electroplating method. Alternatively, the second metal layer 141 may be formed by a lamination method. A method for forming a second metal layer 141 is not limited to the foregoing method, and therefore any method which may form the metal layer on the insulating layer in the circuit board field may be applied.

Referring to FIG. 10, a first via hole 151 and a second via hole 152 are formed.

According to the first exemplary embodiment of the present disclosure, the first via hole 151 is formed to penetrate through the first insulating layer 131 and the second metal layer 141. The so formed first via hole 151 is formed to expose an upper surface of the first circuit layer 110. Further, the second via hole 152 is formed to expose the second electrode 123 of the capacitor 120. According to the first exemplary embodiment of the present disclosure, the first via hole 151 and the second via hole 152 may be formed by a laser drill or a CNC drill. Further, the first via hole 151 and the second via hole 152 may be formed by the laser drill and the CNC drill and by a general method for forming a via hole in the circuit board field.

Referring to FIG. 11, a first via 155 and a second via 156 are formed.

According to the first exemplary embodiment of the present disclosure, the first via 155 may be formed by filling the first via hole 151 with a conductive material. The so formed first via 155 is electrically connected to the first circuit layer 110 by penetrating through the first insulating layer 131.

Further, the second via 156 may be formed by filling the second via hole 152 with a conductive material. The so formed second via 156 is electrically connected to the second electrode 123 of the capacitor 120 by penetrating through the first insulating layer 131.

According to the first exemplary embodiment of the present disclosure, when the first via 155 and the second via 156 are formed, a third metal layer 142 is formed on the second metal layer 141.

According to the first exemplary embodiment of the present disclosure, the third metal layer 142 may be simultaneously formed in the same process as the first via 155 and the second via 156 or may be separately formed by a separate process.

For example, the first via 155 and the second via 156 may be formed by the electroless plating method and the electroplating method. In this case, the third metal layer 142 is simultaneously formed by the electroless plating method and the electroplating method.

Alternatively, the first via 155 and the second via 156 may be formed by a screen printing method using a conductive paste. In this case, after the first via 155 and the second via 156 are formed, the third metal layer 142 is formed by a separate electroless plating process and electroplating process.

A method for forming a second via 156, a third via 172, and a third metal layer 142 according to the first exemplary embodiment of the present disclosure is not limited to the foregoing method.

Further, according to the first exemplary embodiment of the present disclosure, the second metal layer 141 and the third metal layer 142 are individually formed, but one of the second metal layer 141 and the third metal layer 142 may be omitted according to the selection of those skilled in the art.

According to the first exemplary embodiment of the present disclosure, the first via 155, the second via 156, and the third metal layer 142 are made of the conductive material used in the board field. For example, the first via 155, the second via 156, and the third metal layer 142 are made of copper.

According to the first exemplary embodiment of the present disclosure, the plurality of second vias 156 are connected to the capacitor 120 to reduce reactance. Therefore, noise shielding characteristics against an electronic signal are improved.

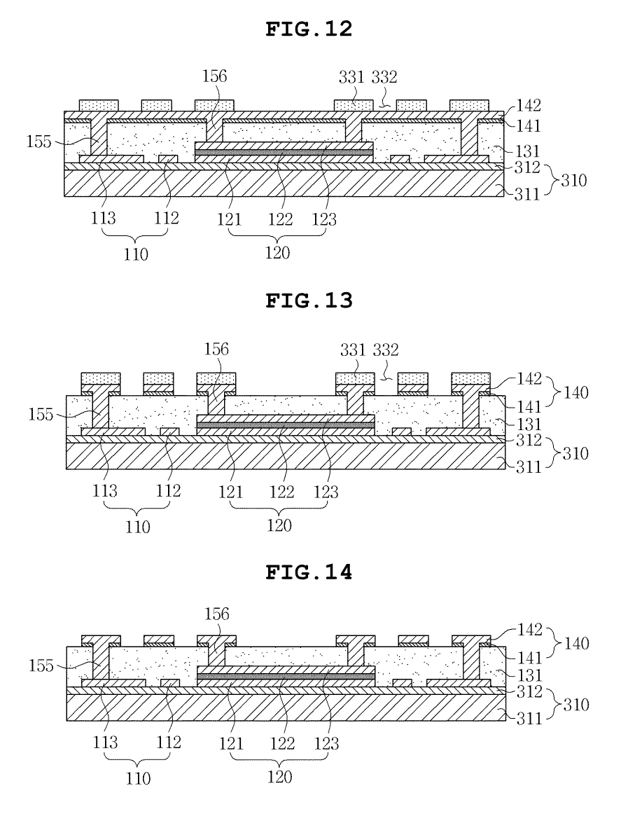

Referring to FIG. 12, a second etching resist 331 is formed.

According to the first exemplary embodiment of the present disclosure, the second etching resist 331 is formed on the third metal layer 142.

The second etching resist 331 includes a second opening 332 through which an area to be removed from the third metal layer 142 is exposed. That is, the second etching resist 331 is formed to protect an area in which the second circuit layer (not illustrated) is formed and expose an area to be removed.

Referring to FIG. 13, the second circuit layer 140 is formed.

According to the first exemplary embodiment of the present disclosure, the etching process is performed on the third metal layer 142. According to the first exemplary embodiment of the present disclosure, in the third metal layer 142, a portion at which the second etching resist 331 is formed is protected from the etching process and a portion exposed to the second opening 332 is removed. In this case, the second metal layer 141 formed beneath the third metal layer 142 is simultaneously removed. As such, the second circuit layer 140 is formed by patterning the second metal layer 141 and the third metal layer 142.

Referring to FIG. 14, the second etching resist 331 (FIG. 13) is removed.

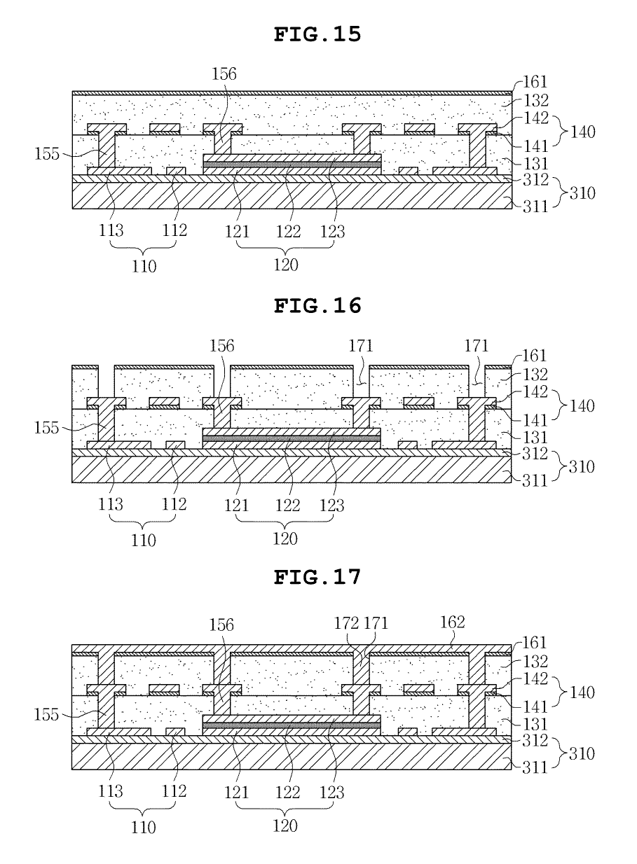

Referring to FIG. 15, the second insulating layer 132 and a fourth metal layer 161 are formed.

According to the first exemplary embodiment of the present disclosure, the second insulating layer 132 is formed on the first insulating layer 131 to embed the first circuit layer 110. According to the first exemplary embodiment of the present disclosure, the second insulating layer 132 is formed by being stacked on the first insulating layer 131 in a high temperature and pressure state. According to the first exemplary embodiment of the present disclosure, the second insulating layer 132 is made of the composite polymer resin which is generally used as an interlayer insulating material. For example, the second insulating layer 132 may be made of an epoxy based resin, such as prepreg, ajinomoto build up film (ABF), FR-4, and bismaleimide triazine (BT). However, according to the first exemplary embodiment of the present disclosure, the material forming the second insulating layer 132 is not limited thereto. According to the first exemplary embodiment of the present disclosure, the second insulating layer 132 may be selected from the insulating materials known in the circuit board field.

According to the first exemplary embodiment of the present disclosure, the fourth metal layer 161 is formed on the second insulating layer 132. For example, the fourth metal layer 161 may be made of copper. However, the material of the fourth metal layer 161 is not limited to copper, and therefore any material which may be used as the conductive material for the circuit in the circuit board field may be applied to the fourth metal layer 161 without being limited. According to the first exemplary embodiment of the present disclosure, the fourth metal layer 161 may be formed by the electroless plating method and the electroplating method. Alternatively, the fourth metal layer 161 may be formed by the lamination method. A method for forming a fourth metal layer 161 according to the first exemplary embodiment of the present disclosure is not limited to the foregoing method, and therefore any method which may form the metal layer on the insulating layer in the circuit board field may be applied.

Referring to FIG. 16, a third via hole 171 is formed.

According to the first exemplary embodiment of the present disclosure, the third via hole 171 is formed to penetrate through the second insulating layer 132 and the fourth metal layer 161. The so formed third via hole 171 is formed to expose the upper surface of the second circuit layer 140. According to the first exemplary embodiment of the present disclosure, the third via hole 171 is formed by the laser drill or the CNC drill. Further, the third via hole 171 may be formed by the laser drill and the CNC drill and by a general method for forming a via hole in the circuit board field.

Referring to FIG. 17, a third via 172 is formed.

According to the first exemplary embodiment of the present disclosure, the third via 172 may be formed by filling the third via hole 171 with a conductive material. The third via 172 is electrically connected to the second circuit layer 140 by penetrating through the second insulating layer 132.

According to the first exemplary embodiment of the present disclosure, when the third via 172 is formed, a fifth metal layer 162 is formed on the fourth metal layer 161.

According to the first exemplary embodiment of the present disclosure, the fifth metal layer 162 may be simultaneously formed in the same process as the third via 172 or may be separately formed by a separate process.

For example, the third via 172 may be formed by the electroless plating method and the electroplating method. In this case, the fifth metal layer 162 is simultaneously formed with the third via 172 by the electroless plating method and the electroplating method. Alternatively, the third via 172 may be formed by the screen printing method using the conductive paste. In this case, after the third via 172 is formed, the fifth metal layer 162 is formed by the separate electroless plating process and electroplating process.

According to the first exemplary embodiment of the present disclosure, a method for forming a second via 156, a third via 172, and a fifth metal layer 162 is not limited to the foregoing method.

Further, according to the first exemplary embodiment of the present disclosure, the fourth metal layer 161 and the fifth metal layer 162 are individually formed but is not limited thereto. That is, one of the fourth metal layer 161 and the fifth metal layer 162 may be omitted according to the selection of those skilled in the art.

The first via 155, the second via 156, and the fifth metal layer 162 are made of the conductive material used in the board field. For example, the first via 155, the second via 156, and the fifth metal layer 162 are made of copper.

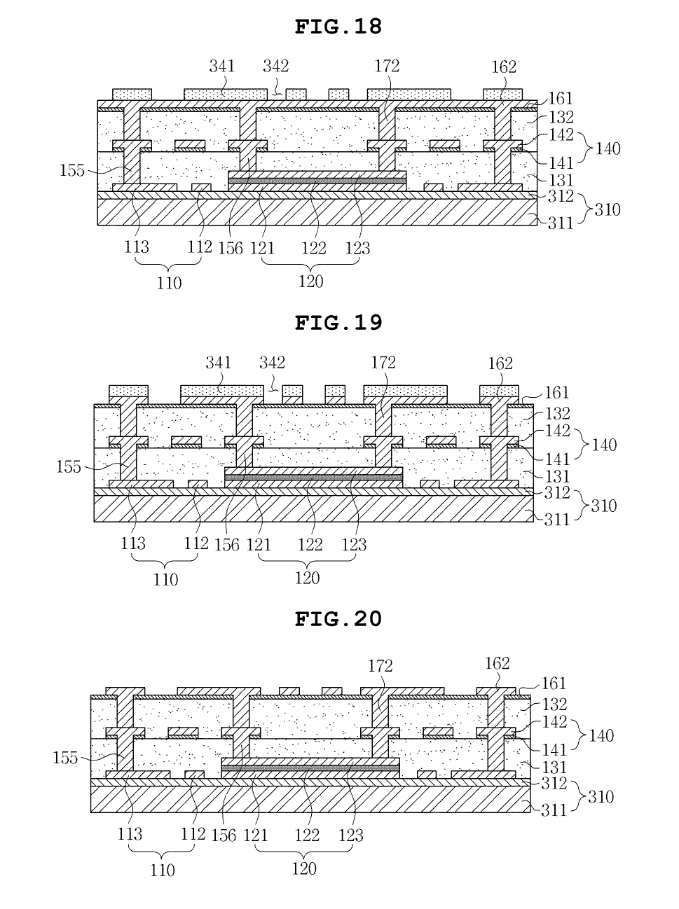

Referring to FIG. 18, a third etching resist 341 is formed.

According to the first exemplary embodiment of the present disclosure, the third etching resist 341 is formed on the fifth metal layer 162.

According to the first exemplary embodiment of the present disclosure, the third etching resist 341 includes a third opening 342 through which an area to be removed from the fifth metal layer 162 is exposed. That is, the third etching resist 341 is formed to protect an area in which the third circuit layer (not illustrated) is formed and expose an area to be removed.

Referring to FIG. 19, the fifth metal layer 162 may be patterned.

According to the first exemplary embodiment of the present disclosure, the etching process is performed on the fifth metal layer 162. In the fifth metal layer 162, a portion at which the third etching resist 341 is formed is protected from the etching process and a portion exposed to the third opening 342 is removed.

The first exemplary embodiment of the present disclosure describes, by way of example, that the fifth metal layer 162 is formed over the fourth metal layer 161 and then is patterned by the etching process. However, the patterned fifth metal layer 162 may be formed by forming a plating resist (not illustrated) on the fourth metal layer 161 and partially performing plating only on the area in which the third circuit layer (not illustrated) is formed.

Referring to FIG. 20, the third etching resist 341 (FIG. 19) is removed.

According to the first exemplary embodiment of the present disclosure, the third etching resist 341 (FIG. 19) is removed and thus the fifth metal layer 162 disposed beneath the third etching resist 341 (FIG. 19) may be exposed.

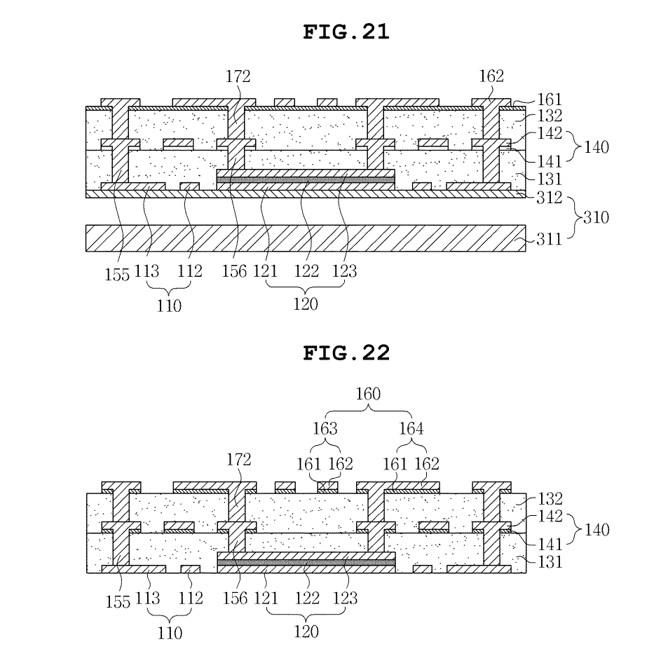

Referring to FIG. 21, the carrier core 311 is removed.

According to the first exemplary embodiment of the present disclosure, the carrier core 311 is removed by separating the carrier core 311 of the carrier board 310 from the carrier metal layer 312.

In this case, according to the first exemplary embodiment of the present disclosure, the carrier metal layer 312 remains intact beneath the first insulating layer 131.

Referring to FIG. 22, the carrier metal layer 312 and the fourth metal layer 161 are removed.

According to the first exemplary embodiment of the present disclosure, the first insulating layer 131, the first circuit layer 110, and the first electrode 121 of the capacitor 120 are exposed by removing the carrier metal layer 312. In this case, the first circuit layer 110 is embedded in the first insulating layer 131 and only a lower surface of the first circuit layer 110 is exposed from the first insulating layer 131. Further, the capacitor 120 is embedded in the first insulating layer 131 and only a lower surface of the first electrode 121 is exposed from the first insulating layer 131.

Further, according to the first exemplary embodiment of the present disclosure, the fifth metal layer 162 exposed to the outside by the removal of the third etching resist 341 (FIG. 19) is etched. The so exposed fourth metal layer 161 is etched to form the third circuit layer 160 including the fourth metal layer 161 and the fifth metal layer 162. According to the first exemplary embodiment of the present disclosure, the third circuit layer 160 includes the third circuit pattern 163 and the external connection pad 164. The external connection pad 164 is electrically connected to the external components such as a semiconductor package and a package board. The so formed third circuit layer 160 has a structure to protrude on the second insulating layer 132.

The first exemplary embodiment of the present disclosure describes, by way of example, that the carrier metal layer 312 and the fourth metal layer 161 are simultaneously removed but is not limited thereto. For example, the fourth metal layer 161 is simultaneously removed with the fifth metal layer 162 exposed by the third etching resist 341 (FIG. 19) in FIG. 19 to form the third circuit layer 160. Further, the carrier metal layer 312 may be removed after the third circuit layer 160 is formed.

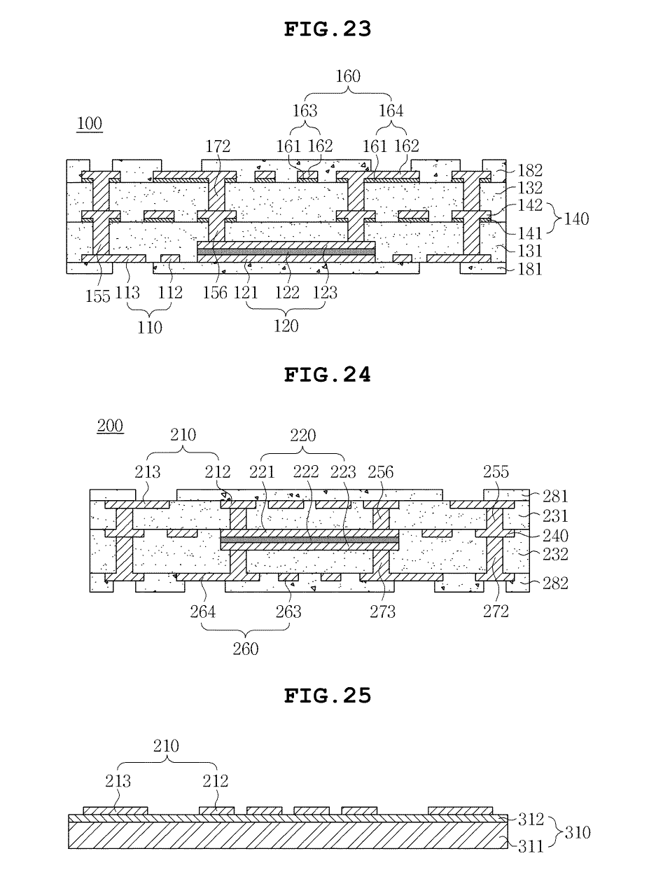

Referring to FIG. 23, the first solder resist layer 181 and the second solder resist layer 182 are formed.

According to the first exemplary embodiment of the present disclosure, the first solder resist layer 181 is formed beneath the first insulating layer 131. The first solder resist layer 181 is formed to enclose the first circuit layer 110 and the first electrode 121 of the capacitor 120. In this case, the first solder resist layer 181 is formed to expose the boding pad 113 of the first circuit layer 110.

According to the first exemplary embodiment of the present disclosure, the second solder resist layer 182 is formed on the second insulating layer 132. The second solder resist layer 182 is formed to enclose the third circuit layer 160. In this case, the second solder resist layer 182 is formed to expose the external connection pad 164 of the third circuit layer 160.

The first exemplary embodiment of the present disclosure describes that the solder resist layers are formed on the first insulating layer 131 and the second insulating layer 132, respectively, but is not limited thereto. That is, the solder resist layer may be formed or may not be formed on any one of the first insulating layer 131 and the second insulating layer according to the selection of those skilled in the art.

According to the first exemplary embodiment of the present disclosure, the first solder resist layer 181 and the second solder resist layer 182 protect the circuit patterns from soldering at the time of soldering which connects the semiconductor device or the external components to the package board 100. Further, the first solder resist layer 181 and the second solder resist layer 182 prevent the circuit patterns from being oxidized. The first solder resist layer 181 and the second solder resist layer 182 may be made of the heat resistant covering material.

The package board 100 of FIG. 1 according to the first exemplary embodiment of the present disclosure is formed by the processes of FIGS. 2 through 23. Here, the package board 100 of FIGS. 2 through 23 is a state in which the upper and lower portions of the package board 100 of FIG. 1 are inverted.

The package board 100 formed according to the first exemplary embodiment of the present disclosure has the capacitor 120 embedded therein to reduce the occurrence of noise due to the increase in the operating speed of the semiconductor device (not illustrated). Further, the thickness of the capacitor 120 is thin and thus the increase in the thickness of the package board 100 is not large. Further, the capacitor 120 and the semiconductor device (not illustrated) are formed to have the equal or similar horizontal section size and thus the rigidity of the package board 100 is improved. Therefore, the warpage of the package board 100 is reduced.

### Second Exemplary Embodiment

FIG. 24 is an exemplified diagram illustrating a package board according to another exemplary embodiment of the present disclosure.

Referring to FIG. 24, a package board 200 may include a first insulating layer 231, a second insulating layer 232, a first circuit layer 210 to a third circuit layer 260, a capacitor 220, a first via 255 to a third via 272, a first solder resist layer 281, and a second solder resist layer 282.

According to a second exemplary embodiment of the present disclosure, the first insulating layer 231 and the second insulating layer 232 may be generally made of a composite polymer resin used as an interlayer insulating material. For example, the first insulating layer 231 and the second insulating layer 232 may be made of an epoxy based resin, such as a prepreg, an ajinomoto build up film (ABF), FR-4, and bismaleimide triazine (BT). However, according to the second exemplary embodiment of the present disclosure, the material forming the first insulating layer 231 and the second insulating layer 232 is not limited thereto. The first insulating layer 231 and the second insulating layer 232 may be selected from insulating materials known in a circuit board field.

According to the second exemplary embodiment of the present disclosure, the second insulating layer 232 is formed beneath the first insulating layer 231.

According to the second exemplary embodiment of the present disclosure, the first circuit layer 210 is formed to be embedded in an upper portion of the first insulating layer 231. The so formed first circuit layer 210 includes a first circuit pattern 212 and a bonding pad 213. The bonding pad 213 may be electrically connected to the semiconductor device (not illustrated) when the semiconductor device (not illustrated) is mounted on the package board 200.

According to the second exemplary embodiment of the present disclosure, a second circuit layer 240 is formed to be embedded in an upper portion of the second insulating layer 232.

According to the second exemplary embodiment of the present disclosure, a third circuit layer 260 is formed beneath the second insulating layer 232. In this configuration, the third circuit layer is formed to protrude from the second insulating layer 232. The so formed third circuit layer 260 includes a third circuit pattern 263 and an external connection pad 264. The external connection pad 264 is electrically connected to the external components such as a semiconductor package and a package board.

The first circuit layer 210 to the third circuit layer 260 are made of a conductive material. For example, the first circuit layer 210 to the third circuit layer 260 are made of copper (Cu). However, the material forming the first circuit layer 210 to the third circuit layer 260 is not limited to copper, and therefore any material which may be used as the conductive material for the circuit in the circuit board field may be applied to the first circuit layer 210 to the third circuit layer 260 without being limited.

Further, according to the second exemplary embodiment of the present disclosure, one of the first circuit layer 210 to the third circuit layer 260 may be a power layer and the other thereof may be a ground layer.

According to the second exemplary embodiment of the present disclosure, the capacitor 220 is a 3-layered thin film capacitor which includes a first electrode 221, a second electrode 223, and a dielectric layer 222 formed between the first electrode 221 and the second electrode 223. According to the second exemplary embodiment of the present disclosure, a horizontal section of the capacitor 220 is formed to be equal or similar to that of the semiconductor device (not illustrated) which will be mounted later.

The capacitor 220 according to the second exemplary embodiment of the present disclosure is formed to be embedded in the upper portion of the second insulating layer 232. In this case, an upper surface of the first electrode 221 of the capacitor 220 contacts a first insulating layer 231.

The package board 200 according to the second exemplary embodiment of the present disclosure has the capacitor 220 embedded therein to reduce the occurrence of noise due to the increase in an operating speed of the semiconductor device (not illustrated). Further, the thickness of the capacitor 220 is thin and thus the increase in the thickness of the package board 200 is not large. Further, the capacitor 220 and the semiconductor device (not illustrated) are formed to have the equal or similar horizontal section size and thus rigidity of the package board 200 is improved. Therefore, a warpage of the package board 200 is reduced. Further, in the package board 200 according to the second exemplary embodiment of the present disclosure, a second via 256 and a third via 272 are formed on and beneath the capacitor 220 to reduce the reactance, thereby improving reliability of signal transmission.

Although not illustrated in FIG. 24, the first electrode 221 of the capacitor 220 is formed to be partially bonded to the second circuit layer 240. Therefore, when the second circuit layer 240 is a power layer, the first electrode 221 of the capacitor 220 may also serve as the power layer.

According to the second exemplary embodiment of the present disclosure, the first via 255 is formed to penetrate through the first insulating layer 231. The first via 255 may electrically connect the first circuit layer 210 to the second circuit layer 240.

According to the second exemplary embodiment of the present disclosure, the second via 256 is formed to penetrate through the first insulating layer 231. The second via 256 may electrically connect the first circuit layer 210 to the first electrode 221 of the capacitor 220.

According to the second exemplary embodiment of the present disclosure, a third via 272 is formed to penetrate through the second insulating layer 232. The third via 272 may electrically connect the second circuit layer 240 to the third circuit layer 260.

According to the second exemplary embodiment of the present disclosure, a fourth via 273 is formed to penetrate through the second insulating layer 232. The fourth via 273 may electrically connect the second electrode 223 of the capacitor 220 to the third circuit layer 260.

According to the second exemplary embodiment of the present disclosure, the first via 255 to the fourth via 273 may be made of the conductive material. For example, the first via 255 to the fourth via 273 are made of copper. However, the material forming the first via 255 to the fourth via 273 is not limited to copper, and therefore any material which may be used as the conductive material for the via in the circuit board field may be applied to the first via 255 to the fourth via 273 without being limited.

According to the second exemplary embodiment of the present disclosure, the first solder resist layer 281 is formed on the first insulating layer 231. The first solder resist layer 281 is formed to enclose the first circuit layer 210 except for an area connected to the outside. That is, the first solder resist layer 281 encloses the first circuit pattern 212 and is formed to expose the bonding pad 213.

According to the second exemplary embodiment of the present disclosure, the second solder resist layer 282 is formed beneath the second insulating layer 232. The second solder resist layer 282 is formed to enclose the third circuit layer 260 except for an area connected to the outside. That is, the second solder resist layer 282 encloses the third circuit pattern 263 and is formed to expose the external connection pad 264.

The second exemplary embodiment of the present disclosure describes that the solder resist layers are formed on the first insulating layer 231 and the second insulating layer 232, respectively, but is not limited thereto. That is, the solder resist layer may be formed or may not be formed on any one of the first insulating layer 231 and the second insulating layer according to the selection of those skilled in the art.

According to the second exemplary embodiment of the present disclosure, the first solder resist layer 281 and the second solder resist layer 282 protect the circuit patterns from soldering at the time of soldering which connects the semiconductor device or the external components to the package board 200. Further, the first solder resist layer 281 and the second solder resist layer 282 prevent the circuit patterns from being oxidized. The first solder resist layer 281 and the second solder resist layer 282 may be made of the heat resistant covering material.

FIGS. 25 through 31 are exemplified diagrams illustrating a method for manufacturing a package board according to another exemplary embodiment of the present disclosure.

In connection with the method for manufacturing a package board according to the second exemplary embodiment of the present disclosure, the same contents as the first exemplary embodiment of the present disclosure will be omitted.

Referring to FIG. 25, the first circuit layer 210 may be formed on the carrier board 310.

According to the second exemplary embodiment of the present disclosure, the carrier board 310 includes the carrier core 311 and the carrier metal layers 312 which are formed on one surface or both surfaces of the carrier core 311.

According to the second exemplary embodiment of the present disclosure, the first circuit layer 210 is formed on the carrier metal layer 312. The first circuit layer 210 includes the first circuit pattern 212 and the bonding pad 213. Here, the bonding pad 213 is electrically connected to the semiconductor device (not illustrated) when the semiconductor device (not illustrated) is mounted on the package board 200.

The method for forming a first circuit layer 210 on a carrier board 310 is the same as the method for forming a first circuit layer 110 according to the first exemplary embodiment of the present disclosure, and therefore the detailed description thereof may refer to the description of FIGS. 2 to 5.

Referring to FIG. 26, the first insulating layer 231 may be formed.

The first insulating layer 231 according to the second exemplary embodiment of the present disclosure may be formed on the carrier metal layer 312 to embed the first circuit layer 210. According to the second exemplary embodiment of the present disclosure, the first insulating layer 231 is formed by being stacked on the carrier metal layer 312 in a high temperature and pressure state. Further, the first insulating layer 231 may be generally made of the composite polymer resin used as the interlayer insulating material.

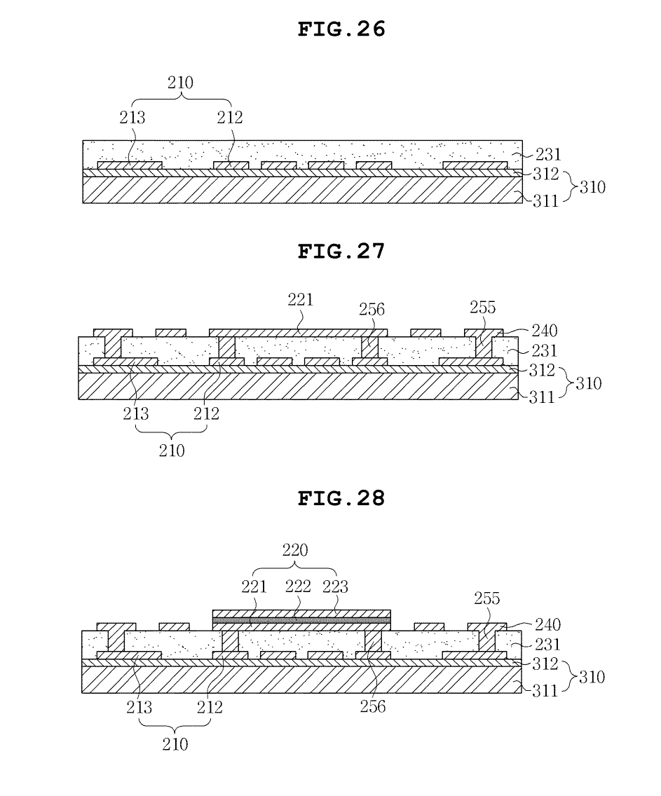

Referring to FIG. 27, the first via 255, the second via 256, the second circuit layer 240, and the first electrode 221 are formed.

According to the second exemplary embodiment of the present disclosure, the first via 255 is formed by forming the first via hole (not illustrated) penetrating through the first insulating layer 231 and then filling the first via hole (not illustrated) with the conductive material. According to the second exemplary embodiment of the present disclosure, the first via 255 is electrically connected to the first circuit layer 210 by penetrating through the first insulating layer 231.

Further, according to the second exemplary embodiment of the present disclosure, the second via 256 is formed by forming the second via hole (not illustrated) penetrating through the first insulating layer 231 and then filling the second via hole (not illustrated) with the conductive material. According to the second exemplary embodiment of the present disclosure, the second via 256 is electrically connected to the first circuit layer 210 by penetrating through the first insulating layer 231.

According to the second exemplary embodiment of the present disclosure, the second circuit layer 240 and the first electrode 221 are formed on the first insulating layer 231. According to the second exemplary embodiment of the present disclosure, the second circuit layer 240 is bonded to the first via 255 and thus is electrically connected to the first circuit layer 210. Further, the first electrode 221 is bonded to the second via 256 and thus is electrically connected to the first circuit layer 210.

According to the second exemplary embodiment of the present disclosure, the first via 255, the second via 256, the second circuit layer 240, and the first electrode 221 all may be simultaneously formed. Alternatively, the first via 255 and the second via 256 may be first formed and then the second circuit layer 240 and the first electrode 221 may be formed later.

Although not illustrated in the present drawing, the second circuit layer 240 is electrically connected to the first electrode 221. In this case, when the second circuit layer 240 is the power layer, the first electrode 221 may also serve as the power layer.

According to the second exemplary embodiment of the present disclosure, any of the materials of the circuit layer and the via and the methods for forming a circuit layer and a via which are applied to the circuit board field may be applied to the first via 255, the second via 256, the second circuit layer 240, and the first electrode 221.

Referring to FIG. 28, the capacitor 220 is formed.

According to the second exemplary embodiment of the present disclosure, the dielectric layer 222 and the second electrode 223 are sequentially formed on the first electrode 221 to form the capacitor 220. The capacitor 220 is the 3-layered thin film capacitor which includes the first electrode 221, the second electrode 223, and the dielectric layer 222. The detailed method for forming a capacitor 220 will be described with reference to FIGS. 7 and 8.

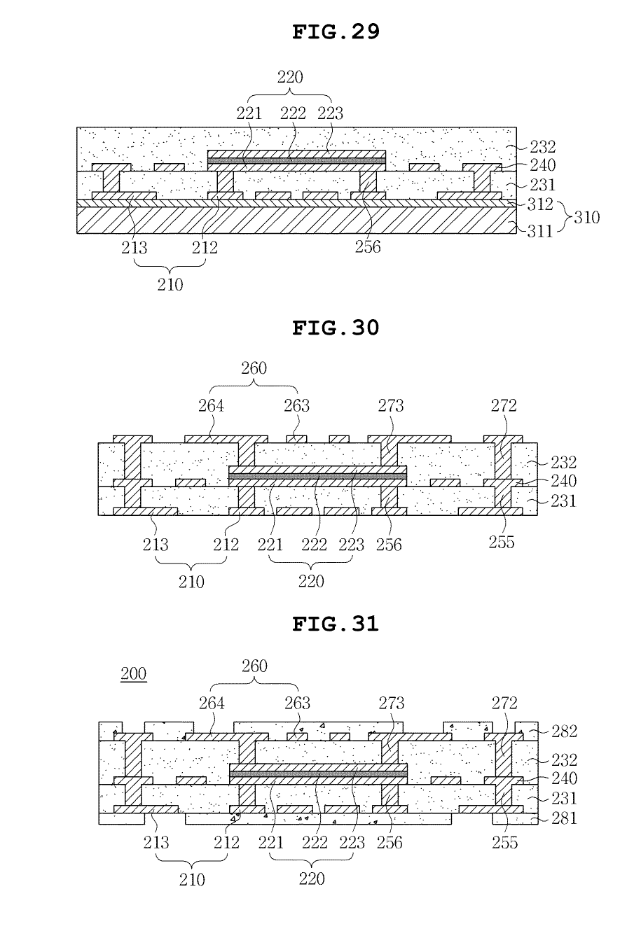

Referring to FIG. 29, the second insulating layer 232 is formed.

According to the second exemplary embodiment of the present disclosure, the second insulating layer 232 is formed on the first insulating layer 231 to embed the second circuit layer 240 and the capacitor 220. According to the second exemplary embodiment of the present disclosure, the second insulating layer 232 is formed by being stacked on the first insulating layer 231 in a high temperature and pressure state. The second insulating layer 232 may be generally made of the composite polymer resin used as the interlayer insulating material.

Referring to FIG. 30, the third via 272, the fourth via 273, and the third circuit layer 260 are formed.

According to the second exemplary embodiment of the present disclosure, the third via 272 is formed by forming the third via hole (not illustrated) penetrating through the second insulating layer 232 and then filling the third via hole (not illustrated) with the conductive material.

Further, according to the second exemplary embodiment of the present disclosure, the fourth via 273 is formed by forming the fourth via hole (not illustrated) penetrating through the second insulating layer 232 and then filling the fourth via hole (not illustrated) with the conductive material.

According to the second exemplary embodiment of the present disclosure, the second via 256 is formed beneath the capacitor 220 and the fourth via 273 is formed thereon. As such, the capacitor 220 is connected to the plurality of vias to reduce the reactance, thereby improving the reliability of signal transmission.

According to the second exemplary embodiment of the present disclosure, the third via 272 and the fourth via 273 are electrically connected to the second circuit layer 240 by penetrating through the second insulating layer 232.

According to the second exemplary embodiment of the present disclosure, the third circuit layer 260 is formed on the second insulating layer 232. The third circuit layer 260 is bonded to the third via 272 and thus is electrically connected to the second circuit layer 240. Further, the third circuit layer 260 is bonded to the fourth via 273 and thus is electrically connected to the second electrode 223 of the capacitor 220. According to the second exemplary embodiment of the present disclosure, the third circuit layer 260 includes the third circuit pattern 263 and the external connection pad 264. The external connection pad 264 is electrically connected to the external components such as a semiconductor package and a package board. The so formed third circuit layer 260 has a structure to protrude on the second insulating layer 232.

According to the second exemplary embodiment of the present disclosure, the third via 272, the fourth via 273, and the third circuit layer 260 all may be simultaneously formed. Alternatively, the third via 272 and the fourth via 273 may be first formed and then the third circuit layer 260 may also be formed later.

According to the second exemplary embodiment of the present disclosure, any of the materials of the circuit layer and the via and the methods for forming a circuit layer and a via which are applied to the circuit board field may be applied to the third via 272, the fourth via 273, and the third circuit layer 260.

According to the second exemplary embodiment of the present disclosure, the carrier board 310 (FIG. 29) is removed before or after the third circuit layer 260 is formed.

According to the second exemplary embodiment of the present disclosure, the detailed description of the method for forming a second insulating layer 232, a third via 272, and a third circuit layer 260 and the method for removing a carrier board 310 (FIG. 28) will be described with reference to FIGS. 15 to 23 of the first exemplary embodiment of the present disclosure. Further, according to the second exemplary embodiment of the present disclosure, the fourth via 273 is formed at a different position from the third via 272 but is formed by the same method as the method for forming a third via 272 and therefore will refer to the method for forming a third via 272.

Referring to FIG. 31, the first solder resist layer 281 and the second solder resist layer 282 are formed.

According to the second exemplary embodiment of the present disclosure, the first solder resist layer 281 and the second solder resist layer 282 are formed to protect the circuit layer from the external environment. For example, the first solder resist layer 281 and the second solder resist layer 282 are formed to protect the circuit layer from soldering or prevent the circuit layer from being oxidized. The first solder resist layer 281 and the second solder resist layer 282 may be made of the heat resistant covering material.

According to the second exemplary embodiment of the present disclosure, the first solder resist layer 281 is formed beneath the first insulating layer 231 to enclose the first circuit layer 210. In this case, the first solder resist layer 281 is formed to expose the bonding pad 213.

Further, the second solder resist layer 282 is formed on the second insulating layer 232 to enclose the third circuit layer 260. In this case, the second solder resist layer 282 is formed to expose the external connection pad 264.

The package board 200 of FIG. 24 according to the second exemplary embodiment of the present disclosure is formed by the processes of FIGS. 25 to 31. The package board 200 of FIGS. 25 to 31 is a state in which the upper and lower portions of the package board 200 of FIG. 24 are inverted.

The package board 200 formed according to the second exemplary embodiment of the present disclosure has the capacitor 220 embedded therein to reduce the occurrence of noise due to the increase in the operating speed of the semiconductor device (not illustrated). Further, the thickness of the capacitor 220 is thin and thus the increase in the thickness of the package board 200 is not large. Further, the capacitor 220 and the semiconductor device (not illustrated) are formed to have the equal or similar horizontal section size and thus the rigidity of the package board 200 is improved. Therefore, the warpage of the package board 200 is reduced.

The exemplary embodiments of the present disclosure describes, by way of example, that the package boards 100 and 200 are provided with the 3-layered insulating layer and the 2-layered circuit layer, but is not limited thereto. That is, the number of layers of the package boards 100 and 200 may be variously implemented according to the selection of those skilled in the art.

Further, the exemplary embodiments of the present disclosure describes, by way of example, that the circuit layer is formed by applying a tenting method. However, the method of forming a circuit layer is not limited to the tenting method. As the method of forming a circuit layer, any of the methods such as a semi-additive process (SAP) and a modify semi-additive process (MSAP) which may be applied in the circuit board field may be applied.

Further, the method for manufacturing package boards 100 and 200 according to the exemplary embodiments of the present disclosure illustrates and describes, by way of example, that the package boards 100 and 200 are formed on one surface of the carrier board 310, but are not limited thereto. That is, the package boards 100 and 200 according to the exemplary embodiments of the present disclosure may be simultaneously formed on both surfaces of the carrier board 300. When the package boards 100 and 200 are formed on both surfaces of the carrier board 300, the two package boards 100 and 200 are simultaneously formed.

Further, the semiconductor devices (not illustrated) mounted on the package boards 100 and 200 according to the exemplary embodiments of the present disclosure may be a memory. That is, when being applied to a single semiconductor package or a stacked semiconductor package, the package board according to the exemplary embodiments of the present disclosure may be applied to the package in which the memory device is mounted.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A package board, comprising:
a first insulating layer;
a second insulating layer formed beneath the first insulating layer;
a capacitor embedded in the first insulating layer and including a first electrode, a second electrode, and a dielectric layer formed between the first electrode and the second electrode;
circuit layers formed on the first insulating layer and the second insulating layer; and
a via formed between the capacitor and the circuit layers or between the circuit layers formed on the first insulating layer and the second insulating layer to electrically connect thererbetween,
wherein an upper surface of the first electrode is formed to be exposed from the first insulating layer.

2. The package board of claim 1, wherein the circuit layer includes:
a first circuit layer formed to be embedded in an upper portion of the first insulating layer;
a second circuit layer formed to be embedded in an upper portion of the second insulating layer; and
a third circuit layer formed beneath the second insulating layer.

3. The package board of claim 2, wherein the via includes:
a first via formed to penetrate through the first insulating layer to electrically connect the first circuit layer to the second circuit layer;
a second via formed to penetrate through the first insulating layer to electrically connect the second electrode of the capacitor to the second circuit layer; and
a third via formed to penetrate through the second insulating layer to electrically connect the second circuit layer to the third circuit layer.

4. The package board of claim 1, wherein the circuit layer further includes at least one of an external connection pad electrically connected to an external connection terminal and a bonding pad electrically connected to a semiconductor device.

5. The package board of claim 1, further comprising:
a solder resist layer formed on at least one of the first insulating layer and the second insulating layer to enclose the circuit layers and patterned to expose an area connected to the outside among the circuit layers.

6. A package board, comprising:
a first insulating layer;
a second insulating layer formed beneath the first insulating layer;
a capacitor embedded in the second insulating layer and including a first electrode, a second electrode, and a dielectric layer formed between the first electrode and the second electrode;
circuit layers formed on the first insulating layer and the second insulating layer; and
a via formed between the capacitor and the circuit layers or between the circuit layers formed on the first insulating layer and the second insulating layer to electrically connect thererbetween,
wherein an upper surface of the first electrode is formed to be exposed from the second insulating layer.

7. The package board of claim 6, wherein the circuit layer includes:
a first circuit layer formed to be embedded in an upper portion of the first insulating layer;
a second circuit layer formed to be embedded in an upper portion of the second insulating layer; and
a third circuit layer formed beneath the second insulating layer.

8. The package board of claim 7, wherein the via includes:
a first via formed to penetrate through the first insulating layer to electrically connect the first circuit layer to the second circuit layer;
a second via formed to penetrate through the first insulating layer to electrically connect the first circuit layer to the first electrode of the capacitor;
a third via formed to penetrate through the second insulating layer to electrically connect the second circuit layer to the third circuit layer; and
a fourth via formed to penetrate through the second insulating layer to electrically connect the second electrode of the capacitor to the third circuit layer.

9. The package board of claim 6, wherein the circuit layer further includes at least one of an external connection pad electrically connected to an external connection terminal and a bonding pad electrically connected to a semiconductor device.

10. The package board of claim 6, further comprising:
a solder resist layer formed on at least one of the first insulating layer and the second insulating layer to enclose the circuit layers and patterned to expose an area connected to the outside among the circuit layers.

11. A method for manufacturing a package board, comprising:
forming a first circuit layer and a first electrode on a carrier board;
forming a dielectric layer on the first electrode;
forming a second electrode on the dielectric layer to form a capacitor including the first electrode, the dielectric layer, and the second electrode;
forming a first insulating layer on the carrier board to embed the first circuit layer and the capacitor;
forming a first via, a second via, and a second circuit layer on the first insulating layer;
forming a second insulating layer on the first insulating layer to embed the second circuit layer;
forming a third via and a third circuit layer on the second insulating layer; and
removing the carrier board.

12. The method of claim 11, wherein in the forming of the first via, the second via, and the second circuit layer, the first via is formed to electrically connect the first circuit layer to the second circuit layer by penetrating through the first insulating layer and the second via is formed to electrically connect the second electrode of the capacitor to the second circuit layer.

13. The method of claim 11, wherein in the forming of the third via and the third circuit layer, the third via is formed to electrically connect the second circuit layer to the third circuit layer by penetrating through the second insulating layer.

14. The method of claim 11, wherein in the forming of the first circuit layer and the first electrode, the first circuit layer further includes at least one of a bonding pad electrically connected to a semiconductor device and an external connection pad electrically connected to an external connection terminal.

15. The method of claim 11, wherein in the forming of the third via and the third circuit layer, the third circuit layer further includes at least one of a bonding pad electrically connected to a semiconductor device and an external connection pad electrically connected to an external connection terminal.

16. The method of claim 11, further comprising:
after the removing of the carrier board, forming a first solder resist layer formed on the first insulating layer and the first circuit layer and patterned to expose an area connected to the outside in the first circuit layer; and
forming a second solder resist layer formed on the second insulating layer and the third circuit layer and patterned to expose an area connected to the outside in the third circuit layer.

17. A method for manufacturing a package board, comprising:
forming a first circuit layer on a carrier board;
forming a first insulating layer on the carrier board to embed the first circuit layer;
forming a second circuit layer, a first via, a second via, and a first electrode on the first insulating layer;
forming a dielectric layer on the first electrode;
forming a second electrode on the dielectric layer to form a capacitor including the first electrode, the dielectric layer, and the second electrode;
forming a second insulating layer on the first insulating layer to embed the second circuit layer and the capacitor;
forming a third via, a fourth via, and a third circuit layer on the second insulating layer; and
removing the carrier board.

18. The method of claim 17, wherein in the forming of the second circuit layer, the first via, the second via, and the first electrode, the first via is formed to electrically connect the first circuit layer to the second circuit layer by penetrating through the first insulating layer and the second via is formed to electrically connect the first circuit layer to the first electrode of the capacitor by penetrating through the first insulating layer.

19. The method of claim 17, wherein in the forming of the third via, the fourth via, and the third circuit layer, the third via is formed to electrically connect the second circuit layer to the third circuit layer by penetrating through the second insulating layer and the fourth via is formed to electrically connect the second electrode to the third circuit layer by penetrating through the second insulating layer.

20. The method of claim 17, wherein in the forming of the first circuit layer, the first circuit layer further includes at least one of a bonding pad electrically connected to a semiconductor device and an external connection pad electrically connected to an external connection terminal.

21. The method of claim 17, wherein in the forming of the third via, the fourth via, and the third circuit layer, the third circuit layer further includes at least one of a bonding pad electrically connected to a semiconductor device and an external connection pad electrically connected to an external connection terminal.

22. The method of claim 17, further comprising:
after the removing of the carrier board, forming a first solder resist layer formed on the first insulating layer and the first circuit layer and patterned to expose an area connected to the outside in the first circuit layer; and
forming a second solder resist layer formed on the second insulating layer and the third circuit layer and patterned to expose an area connected to the outside in the third circuit layer.
